(19) United States
(12) Patent Application Publication
(10) Pub. No.: US 2025/0377311 A1
(43) Pub. Date: Dec. 11, 2025

(54) METHOD FOR MEASURING SEMICONDUCTOR DEVICE

(71) Applicant: SAMSUNG ELECTRONICS CO., LTD., Suwon-si (KR)

(72) Inventors: Seungwoo Lee, Suwon-si (KR); Jinwoo Ahn, Suwon-si (KR); Sooseok Lee, Suwon-si (KR); Jaeho Kim, Suwon-si (KR); Hyo Jeong Son, Suwon-si (KR); Changwon O, Suwon-si (KR)

(73) Assignee: SAMSUNG ELECTRONICS CO., LTD., Suwon-si (KR)

(21) Appl. No.: 18/966,986

(22) Filed: Dec. 3, 2024

(30) Foreign Application Priority Data
Jun. 7, 2024 (KR) 10-2024-0074414

(51) Int. Cl. G01N 21/95; G01N 21/21; G01N 21/31

(52) U.S. Cl. CPC G01N 21/9501; G01N 21/21; G01N 21/31

(57) ABSTRACT

Provided a method for measuring a semiconductor device by an electronic device, including a light source assembly including a light source configured to emit light and a first optical system in a traveling path of the light, a light reception assembly including a second optical system in a traveling path of reflected light which is reflected from a target sample and a detector configured to detect the reflected light, and a processor configured to process an electrical signal from the light reception assembly and obtain a dispersion of a critical dimension of the target sample, the method including obtaining polarization spectrum data corresponding to a change in a polarization state of the reflected light based on the electrical signal, extracting depolarization information corresponding to a degree of depolarization in the reflected light, and obtaining the dispersion of the critical dimension of the target sample based on the depolarization information.

### CROSS-REFERENCE TO RELATED APPLICATION

This application claims priority to Korean Patent Application No. 10-2024-0074414, filed in the Korean Intellectual Property Office on Jun. 7, 2024, the disclosure of which is incorporated herein in its entirety by reference.

### BACKGROUND

### 1. Field

Embodiments of the present disclosure relate to a method for measuring a semiconductor device.

### 2. Description of Related Art

Optical Critical Dimension (OCD) techniques are non-contact measurement of critical dimensions and are used to precisely analyze sizes and shapes of patterns through optical methods. When the OCD technique is used, there is an advantage that it is possible to characterize the shape of a target sample in a non-contact manner and thus make measurements at a high speed without damaging sensitive semiconductor patterns.

However, the OCD technique has a disadvantage in that its accuracy is lower than that of destructive methods such as imaging methods. For this reason, when the OCD technique is used, a local average within each measurement area may be measured relatively accurately, but it is difficult to measure a local dispersion within each measurement area accurately. In other words, a dispersion within a relatively large area such as a wafer may be measured relatively accurately by calculating local averages within each measurement area, but there is a problem in that it is difficult to measure the local dispersion within each measurement area (e.g., within a cell) accurately.

### SUMMARY

One or more embodiments provide a method for measuring a semiconductor device.

According to an aspect of one or more embodiments, there is provided a method for measuring a semiconductor device by an electronic device, wherein the electronic device includes a light source assembly including a light source configured to emit light and a first optical system in a traveling path of the light emitted from the light source, a light reception assembly including a second optical system in a traveling path of reflected light which is reflected from a target sample after passing through the first optical system, and a detector configured to detect the reflected light that passed through the second optical system, and at least one processor configured to process an electrical signal outputted from the light reception assembly and obtain a dispersion of a critical dimension of the target sample, the method including obtaining polarization spectrum data corresponding to a change in a polarization state of the reflected light based on the electrical signal outputted by the light reception assembly, extracting, based on the polarization spectrum data, depolarization information corresponding to a degree of depolarization in the reflected light, and obtaining the dispersion of the critical dimension of the target sample based on the depolarization information.

According to another aspect of one or more embodiments, there is provided a method for measuring a semiconductor device using an electronic device, wherein the electronic device includes an ellipsometer configured to output an electrical signal for a critical dimension of the target sample by emitting incident light having a specific polarization state to a target sample, and detecting reflected light reflected from the target sample, and at least one processor configured to process the electrical signal outputted by the ellipsometer and calculate a dispersion of the critical dimension of the target sample, the method including obtaining, polarization spectrum data corresponding to a change in the polarization state of the reflected light based on the electrical signal outputted by the ellipsometer, extracting, based on the polarization spectrum data, depolarization information corresponding to a degree of depolarization in the reflected light, and obtaining the dispersion of the critical dimension of the target sample based on the depolarization information.

According to yet another aspect of one or more embodiments, there is provided a method for measuring a semiconductor device, the method being performed by at least one processor and including obtaining polarization spectrum data corresponding to a change in a polarization state of reflected light reflected from a target sample based on an electrical signal outputted by an ellipsometer, extracting, based on the polarization spectrum data, depolarization information corresponding to a degree of depolarization in the reflected light, and obtaining the dispersion of the critical dimension of the target sample based on the depolarization information.

### BRIEF DESCRIPTION OF DRAWINGS

The above and other objects, features and advantages of the present disclosure will be described with reference to the accompanying drawings described below, where similar reference numerals indicate similar elements, but not limited thereto, in which:

FIG. 1 is a diagram provided to explain a method for acquiring information on a critical dimension of a target sample;

FIG. 2 is a configuration diagram illustrating an example of an electronic device according to one or more embodiments;

FIG. 3 is a block diagram illustrating an example of a controller according to one or more embodiments;

FIG. 4 is a diagram illustrating an example of extracting depolarization information based on polarization spectrum data according to one or more embodiments;

FIG. 5 is a diagram illustrating examples of product-decomposed sub-matrices according to one or more embodiments;

FIG. 6 is a diagram illustrating examples of sum-decomposed sub-matrices according to one or more embodiments;

FIG. 7 is a diagram illustrating an example of an index related to a degree of depolarization according to one or more embodiments;

FIG. 8 is a diagram illustrating an example of calculating depolarization information using a dispersion prediction model according to one or more embodiments;

FIG. 9 is a diagram illustrating an example of a data set for training a dispersion prediction model according to one or more embodiments;

FIG. 10 is a diagram illustrating an example of a method for generating a dispersion prediction model according to one or more embodiments;

FIG. 11 is a diagram illustrating an example of a method for generating a dispersion prediction model according to one or more embodiments;

FIG. 12 is a diagram illustrating an example of calculating a local dispersion according to one or more embodiments;

FIG. 13 is a diagram illustrating an example of calculating a local dispersion according to one or more embodiments;

FIG. 14 is a diagram illustrating an example of an experimental result showing a correlation between depolarization information and a local dispersion of a critical dimension according to one or more embodiments;

FIG. 15 is a diagram illustrating an example of a degree of consistency between a local dispersion calculated according to various methods and a reference local dispersion according to one or more embodiments; and

FIG. 16 is a flowchart illustrating an example of a method for calculating a local dispersion of a critical dimension according to one or more embodiments.

### DETAILED DESCRIPTION

Hereinafter, example details for the practice of the present disclosure will be described in detail with reference to the accompanying drawings. However, in the following description, detailed descriptions of well-known functions or configurations will be omitted if it may make the subject matter of the present disclosure rather unclear.

It will be understood that, although the terms first, second, third, fourth, etc. may be used herein to describe various elements, components, regions, layers and/or sections (collectively “elements”), these elements should not be limited by these terms. These terms are only used to distinguish one element from another element. Thus, a first element described in this description section may be termed a second element or vice versa in the claim section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

As used herein, an expression “at least one of” preceding a list of elements modifies the entire list of the elements and does not modify the individual elements of the list. For example, an expression, “at least one of a, b, and c” should be understood as including only a, only b, only c, both a and b, both a and c, both b and c, or all of a, b, and c.

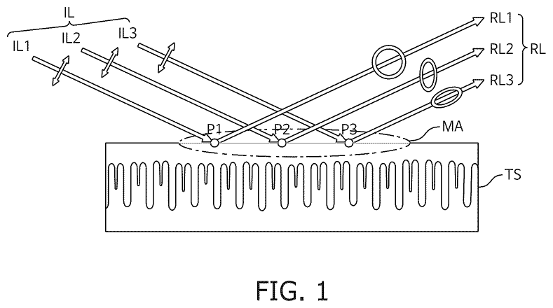

FIG. 1 is a diagram provided to explain a method for acquiring information on a critical dimension of a target sample (TS) according to one or more embodiments. An electronic device may non-destructively acquire information on a critical dimension CD of a target sample TS by emitting incident light IL having a specific polarization state toward the target sample TS and identifying a change in the polarization state of reflected light RL reflected from the target sample TS.

The critical dimension may refer to a physical dimension of a specific structure or a specific feature of the target sample TS. The target sample TS may include at least a part of a semiconductor device or a semiconductor element, and in this case, the critical dimension may include a critical dimension of a fine pattern included in the semiconductor device or the semiconductor element. For example, the target sample TS may include at least a part of a semiconductor memory device, and the critical dimension may include a diameter of a channel hole included in the semiconductor memory device. In another example, the critical dimension may include a height of a channel included in the semiconductor memory device.

For example, the incident light IL having the specific polarization state may be emitted to a measurement area MA of the target sample TS. The measurement area MA may be an area of the target sample TS to which incident light IL is emitted. The polarization state in the reflected light RL reflected from the measurement area MA of the target sample TS may change according to characteristics within the measurement area MA of the target sample TS.

For example, a polarization state of first reflected light RL1 reflected from a first point P1 within the measurement area MA of the target sample TS may be changed compared to first incident light IL1 emitted to the first point P1 according to characteristics (e.g., thickness, refractive index, absorption coefficient, etc.) of the first point P1 of the target sample TS. A polarization state of second reflected light RL2 reflected from a second point P2 within the measurement area MA of the target sample TS may be changed compared to second incident light IL2 emitted to the second point P2 according to characteristics of the second point P2 of the target sample TS. A polarization state of third reflected light RL3 reflected from a third point P3 within the measurement area MA of the target sample TS may be changed compared to third incident light IL3 emitted to the third point P3 according to characteristics of the third point P3 of the target sample TS.

As shown in FIG. 1, the first to third incident light IL1, IL2, and IL3 with the same polarization state or a corresponding polarization state (e.g., the same degree of circular polarization and the same main axis direction of a polarization ellipse) may be emitted to the target sample TS. The first to third points P1, P2, and P3 may have different characteristics from one another. Accordingly, the second reflected light RL2 and the third reflected light RL3 may be different from the first reflected light RL1 in the degree of circular polarization, and the second reflected light RL2 may be different from the third reflected light RL3 in the main axis direction of the polarization ellipse.

The electronic device may acquire (obtain) information on the critical dimension of the target sample TS by identifying a change in the polarization state of the reflected light RL compared to the polarization state of the incident light IL. For example, the electronic device may calculate (obtain) a local average representing an average of a critical dimension within the measurement area MA of the target sample TS based on polarization spectrum data representing the change in the polarization state of the reflected light RL. In another example, the electronic device may calculate a local dispersion representing a dispersion of the critical dimension within the measurement area MA of the target sample TS based on the polarization spectrum data representing the change in the polarization state of the reflected light RL. When the target sample TS has a multi-layered structure, the electronic device may acquire information on a critical dimension of each layer under the measurement area MA by identifying a change in the polarization state of the reflected light RL. According to some examples, the change in the polarization state of the reflected light RL may refer to a change in the polarization state of the reflected light RL compared to the polarization state of the incident light IL.

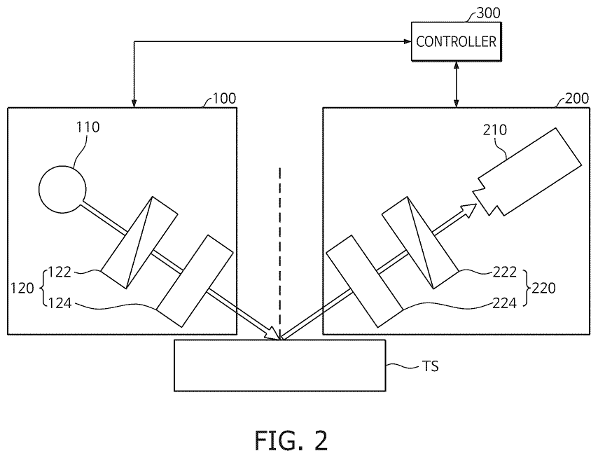

FIG. 2 is a configuration diagram illustrating an example of an electronic device according to one or more embodiments. Referring to FIG. 2, the electronic device may include an ellipsometer that measures a target sample TS and a controller 300 electrically connected with the ellipsometer. The ellipsometer may irradiate incident light to the target sample TS, detect reflected light reflected from the target sample TS, and output an electrical signal corresponding to the detected reflected light. The controller 300 may acquire information on the target sample TS by processing the electrical signal outputted by the ellipsometer. The electrical signal may include all types of electrical signals related to reflected light outputted by the ellipsometer, and may include, for example, analog signals, digital signals, data, images, etc.

The ellipsometer may include a light source unit (assembly) 100 and a light reception unit 200.

The light source unit 100 may include a light source 110 that emits light, and a first optical system 120 disposed in a traveling path of light emitted from the light source 110. The light source 110 may emit light including various wavelengths. A wavelength band included in the light emitted by the light source 110 may vary according to ellipsometer facilities, etc. For example, the light source may be a xenon lamp, a halogen lamp, a laser, etc., but the light source 110 is not limited thereto. The light emitted by the light source 110 may be incident light that passed through the first optical system 120 and emitted to the target sample TS.

The first optical system 120 may include a polarizer 122 that polarizes the light emitted from the light source 110 into a specific polarization state (e.g., a linear polarization state, etc.). For example, the polarizer 122 may be a diffraction grating, a prism, a Polaroid filter, etc., but is not limited thereto. The first optical system 120 may further include a first compensator 124. The first compensator 124 may correct a polarization state of light and/or precisely adjust a phase difference by modulating the phase of light passed through the polarizer 122.

The light reception unit 200 may include a second optical system 220 disposed in a traveling path of reflected light reflected from the target sample TS, and a detector 210 that detects the reflected light passed through the second optical system 220. The second optical system 220 may include an analyzer 222 for analyzing the polarization state of the reflected light. The analyzer 222 may be implemented in the same or similar configuration as the polarizer 122, but is not limited thereto. The second optical system 220 may further include a second compensator 224. The reflected light reflected from the target sample TS may have a phase modulated by the second compensator 224. Accordingly, the detector 210 may more accurately detect the polarization state of the reflected light.

The detector 210 may detect the reflected light passed through the second optical system 220. For example, the detector 210 may detect an intensity of light passed through the second optical system 220 and output an electrical signal corresponding to the detected intensity of light. The detector 210 may measure a spectrum representing an intensity of the light passed through the second optical system 220 by wavelength, and may output an electrical signal corresponding to the measured spectrum.

The configuration of the ellipsometer described above is only an example, but is not limited thereto. For example, the ellipsometer may include various optical elements (e.g., a spectrometer, a monochromator, a beam splitter, an auxiliary polarizer, etc.) in addition to or alternatively to the above-described elements.

The controller 300 may process the electrical signal outputted by the ellipsometer (e.g., the light reception unit 200 or the detector 210) to acquire information on a critical dimension of the target sample TS. For example, the controller 300 may process the electrical signal outputted by the ellipsometer to calculate a local dispersion of a critical dimension within a measurement area of the target sample TS (e.g., a standard deviation of the critical dimension within the measurement area). In this regard, the disclosure will be described in more detail below.

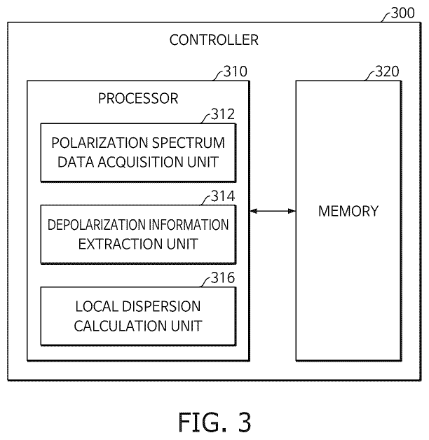

FIG. 3 is a block diagram illustrating an example of the controller 300. Referring to FIG. 3, the controller 300 may include a memory 320 in which one or more instructions are stored, and a processor 310 for executing one or more instructions stored in the memory 320. Although the processor 310 is illustrated as being a single processor 310 in FIG. 3, the scope of the disclosure is not limited thereto. For example, the processor 310 may include one or more processors.

The memory 320 may include any electronic component capable of storing electronic information. For example, the memory 320 may refer to various types of processor-readable media such as a random access memory (RAM), a read-only memory (ROM), a nonvolatile random access memory (NVRAM), a programmable read-only memory (PROM), an erasable programmable read-only memory (EPROM), an electrically erasable PROM (EEPROM), a flash memory, a magnetic or optical data storage, a disk drive, a solid state drive (SSD), a register, etc. In an example, a nonvolatile mass storage device such as a ROM, a SSD, a flash memory, a disk drive, etc. may be included in the controller 300 as a separate permanent storage device that is distinguished from the memory 320.

The memory 320 may store an operating system and at least one program code (e.g., a code for acquiring polarization spectrum data, extracting depolarization information, calculating a local dispersion) including one or more instructions. In one example, these software components may be loaded from a computer-readable recording medium in a computer separate from the memory 320. In another example, the software components may be loaded into the memory 320 through the communication module (not illustrated) rather than the computer-readable recording medium. For example, at least one program code may be loaded into the memory 320 based on a computer program installed by files provided by developers or a file distribution system that distributes an installation file of an application through the network.

The processor 310 may be configured to process the commands of the computer program by performing basic arithmetic, logic, and input and output operations. The commands may be provided to the processor 310 from the memory 320 or the communication module. For example, the processor 310 may be configured to execute the received commands according to a program code stored in a recording device such as the memory 320.

In FIG. 3 and the following descriptions, internal components of the processor 310 will be described, respectively, for their functions, but this is only for the convenience of explanation and does not necessarily indicate that the internal components of the processor 310 are physically separated.

The processor 310 may include a polarization spectrum data acquisition unit 312, a depolarization information extraction unit 314, and a local dispersion calculation unit 316.

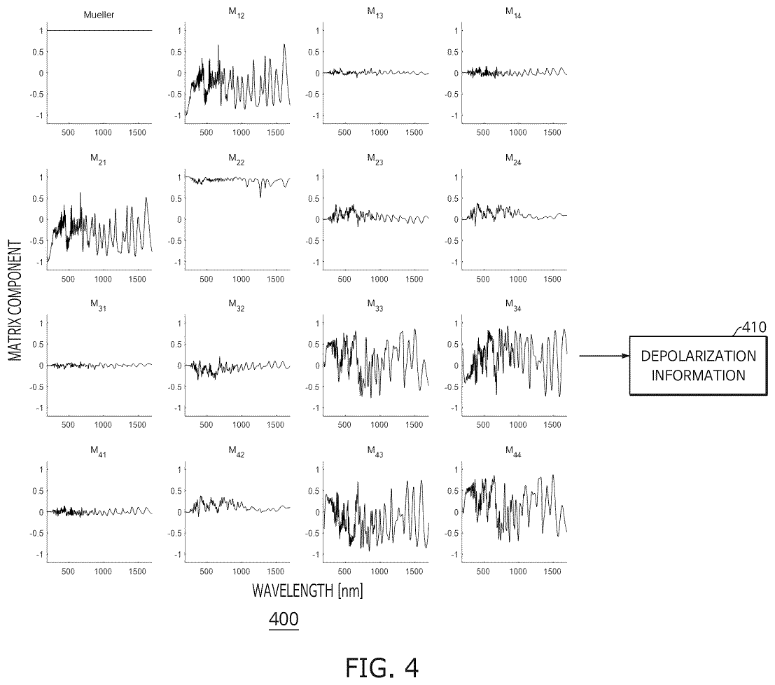

The polarization spectrum data acquisition unit 312 may acquire polarization spectrum data representing a change in the polarization state of reflected light based on an electrical signal outputted by the ellipsometer. For example, the polarization spectrum data acquisition unit 312 may acquire elliptical polarization parameters (e.g., an amplitude ratio (w) and a phase differences (4)) of reflected light based on the electrical signal outputted by the ellipsometer. Additionally or alternatively, the polarization spectrum data acquisition unit 312 may calculate a Mueller matrix representing a change in the polarization state of each wavelength of the reflected light. This will be described below in detail with reference to FIG. 4.

The depolarization information extraction unit 314 may extract depolarization information based on the polarization spectrum data. The depolarization information may include information related to the degree to which the polarization state in the reflected light is reduced (i.e., the degree of depolarization) compared to incident light. This will be described in more detail below with reference to FIGS. 4 to 7.

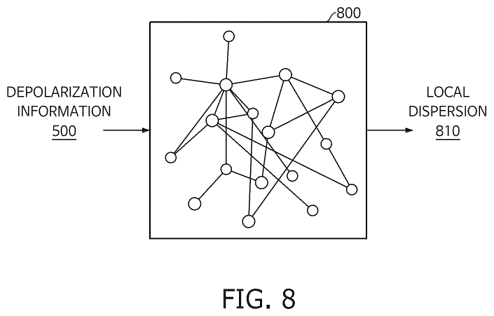

The local dispersion calculation unit 316 may calculate a local dispersion of a critical dimension of a target sample based on the extracted depolarization information. The local dispersion calculation unit 316 may calculate a local dispersion (e.g., a standard deviation of the critical dimension within the measurement area) by using a dispersion prediction model which is modeled to output a local dispersion based on inputted depolarization information. This will be described in more detail below with reference to FIGS. 8 to 11.

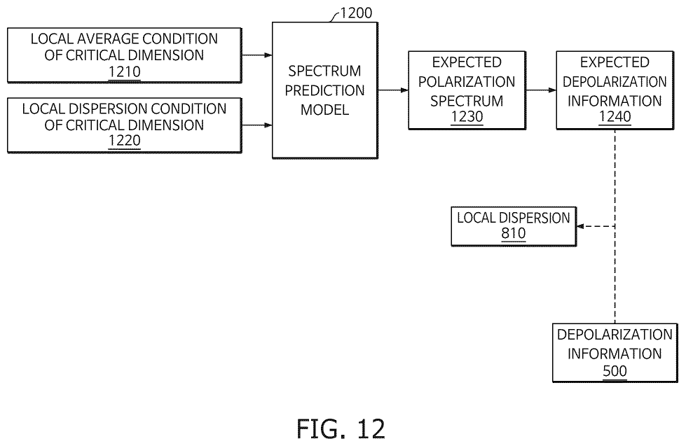

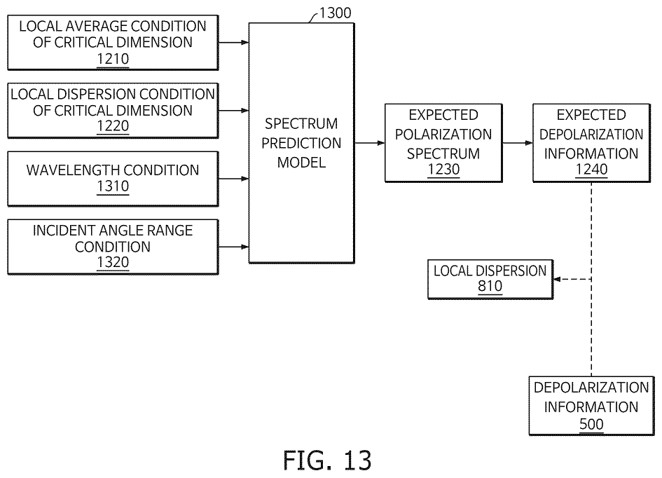

Additionally or alternatively, the local dispersion calculation unit 316 may calculate the local dispersion by using a model representing expected polarization spectrum data according to a local average condition of the critical dimension and a local dispersion condition of the critical dimension. This will be described in more detail below with reference to FIGS. 12 and 13.

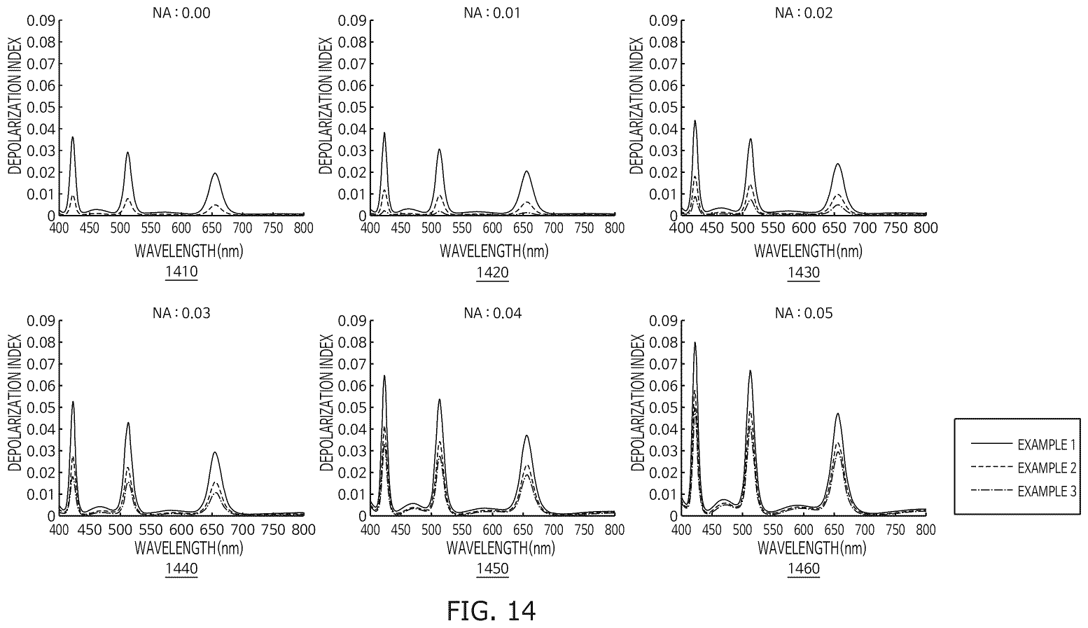

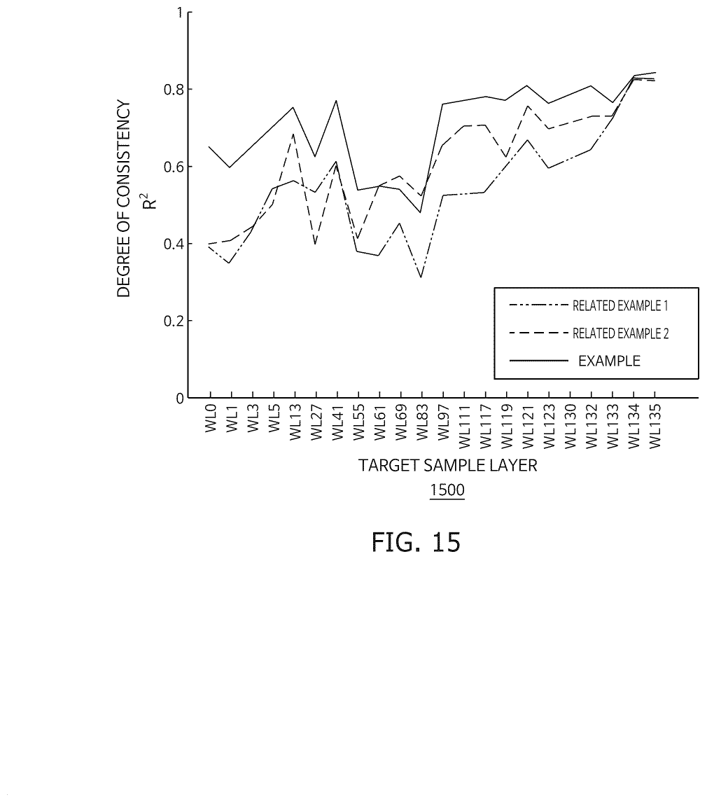

As described above, when the local dispersion is calculated by using the depolarization information, more accurate dispersion information may be acquired than when the local dispersion is calculated by using the entire polarization spectrum data. This will be described in more detail below with reference to FIGS. 14 and 15.

In one or more embodiments, the controller 300 may calculate the local dispersion of the critical dimension, but embodiments are not limited thereto. The controller 300 may calculate a dispersion of the critical dimension. Although it will be described below that the controller 300 calculates the local dispersion of the critical dimension, the controller 300 may calculate a dispersion of the critical dimension.

FIG. 4 is a diagram illustrating an example of extracting depolarization information 410 based on polarization spectrum data. Referring to FIG. 4, the controller may acquire polarization spectrum data representing a change in the polarization state of reflected light based on an electrical signal outputted by the ellipsometer. For example, the controller may calculate a Mueller matrix for each wavelength of reflected light based on the electrical signal outputted by the ellipsometer. The Mueller matrix may be a 4×4 matrix representing a change in the polarization state. The Mueller matrix may be a matrix representing a relationship between a Stokes vector of incident light and a Stokes vector of reflected light. For example, the Mueller matrix may be expressed as shown in Equation 1.

$$M = ( \begin{matrix}\begin{matrix}\begin{matrix}{M}_{11} \\ {M}_{21}\end{matrix} \\ {M}_{31}\end{matrix} \\ {M}_{41}\end{matrix} \begin{matrix}\begin{matrix}\begin{matrix}{M}_{12} \\ {M}_{22}\end{matrix} \\ {M}_{32}\end{matrix} \\ {M}_{42}\end{matrix} \begin{matrix}\begin{matrix}\begin{matrix}{M}_{13} \\ {M}_{23}\end{matrix} \\ {M}_{33}\end{matrix} \\ {M}_{43}\end{matrix} \begin{matrix}\begin{matrix}\begin{matrix}{M}_{14} \\ {M}_{24}\end{matrix} \\ {M}_{34}\end{matrix} \\ {M}_{44}\end{matrix} ) \qquad 〈 Equation 1 〉$$

FIG. 4 illustrates an example 400 of the Mueller matrix by wavelength. In the illustrated example 400, the horizontal axis of each matrix component may represent a wavelength and the vertical axis may represent a value of the matrix component.

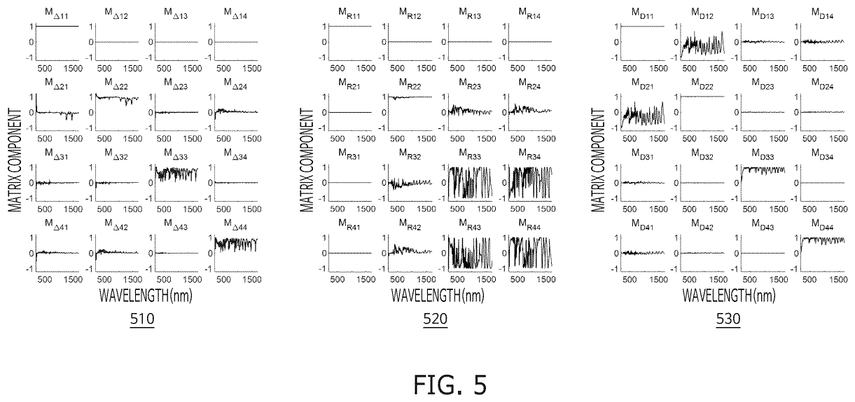

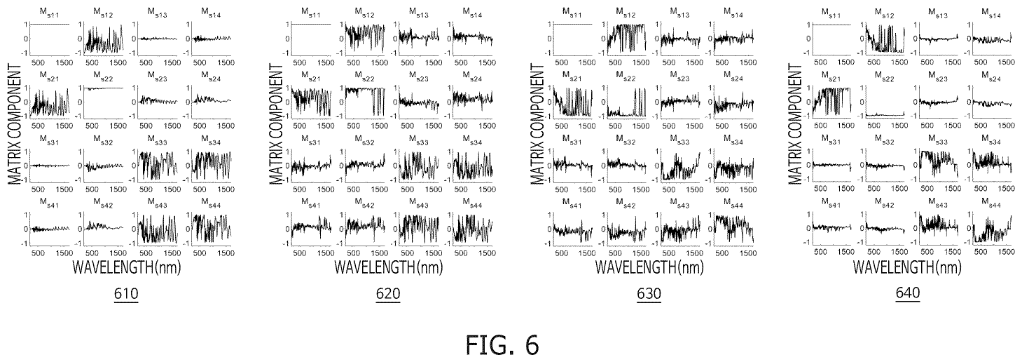

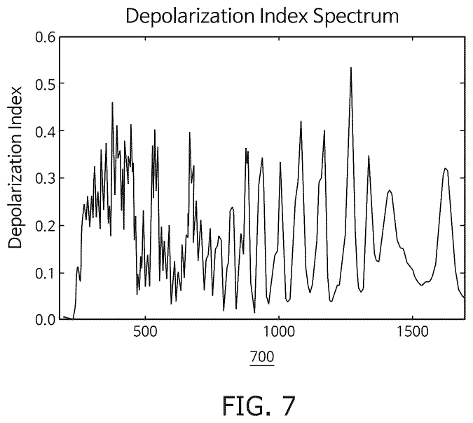

The controller may extract the depolarization information 410 based on the polarization spectrum data. The depolarization information 410 may include information related to the degree to which the polarization state in the reflected light is reduced compared to incident light (i.e., the degree of depolarization). The controller may extract the depolarization information 410 by decomposing the Mueller matrix into a plurality of sub-matrices. This will be described in more detail below with reference to FIGS. 5 and 6. Additionally or alternatively, the controller may extract the depolarization information 410 by calculating an index related to the degree to which the polarization state is reduced based on the Mueller matrix. This will be described below in more detail with reference to FIG. 7.

FIG. 5 is a diagram illustrating examples 510, 520, and 530 of product-decomposed sub-matrices. The controller may extract depolarization information by performing product decomposition with respect to the Mueller matrix.

The controller may decompose the Mueller matrix into a product of a plurality of sub-matrices associated with a change element of the polarization state of reflected light. For example, the controller may decompose the Mueller matrix into a product of a polarization transformation matrix associated with a depolarization element of reflected light, a polarization rotation matrix associated with a phase retardation element of reflected light, and a polarization diattenuation matrix associated with a polarization diattenuation element of reflected light. As a specific example, the Mueller matrix may be product-decomposed as shown in Equation 2.

$$M = {M}_{Δ} {M}_{R} {M}_{D} \qquad 〈 Equation 2 〉$$

Here, M may represent the Mueller matrix, MA may represent the polarization transformation matrix, MR may represent the polarization rotation matrix, and Mp may represent the polarization diattenuation matrix.

Since the Mueller matrix may be calculated for each wavelength, the sub-matrices into which the Mueller matrix is decomposed may also be calculated for each wavelength. FIG. 5 illustrates examples 510, 520, 530 of product-decomposed sub-matrices. The first example 510 shows an example of the polarization transformation matrix, the second example 520 shows an example of the polarization rotation matrix, and the third example 530 shows an example of the polarization diattenuation matrix. In the illustrated examples 510, 520, 530, the horizontal axis of each matrix component may represent a wavelength and the vertical axis may represent a value of the matrix component. For example, the polarization transformation matrix may be related to the degree to which polarization of light is reduced or to the degree to which several polarizations are mixed. The polarization rotation matrix may be related to the degree to which the phase of light is delayed. The polarization diattenuation matrix may be related to the degree to which the size of the electric field component of is reduced or the amount of light is reduced.

The controller may use at least some of the plurality of decomposed sub-matrices (or a result of performing an appropriate operation on at least some of the decomposed sub-matrices) as depolarization information. For example, the controller may use the polarization transformation matrix (or some components of the polarization transformation matrix) associated with the depolarization element among the product-decomposed sub-matrices as depolarization information.

FIG. 5 illustrates an example in which the controller decomposes the Mueller matrix into the product of the polarization transformation matrix, the polarization rotation matrix, and the polarization diattenuation matrix, but embodiments are not limited thereto. For example, the controller may perform product-decomposition by using an inverse matrix or a transposed matrix for at least some of the polarization transformation matrix, the polarization rotation matrix, and the polarization diattenuation matrix, omitting some matrices, or adding another matrix.

FIG. 6 is a diagram illustrating examples 610, 620, 630, and 640 of sum-decomposed sub-matrices. The controller may extract depolarization information by performing sum decomposition with respect to the Mueller matrix.

The controller may decompose the Mueller matrix into a sum. For example, the controller may decompose the Mueller matrix into a weighted sum of a plurality of non-depolarizing sub-matrices. As a specific example, the Mueller matrix may be sum-decomposed as shown in Equation 3.

$$M = {λ}_{1} {M}_{1} + {λ}_{2} {M}_{2} + {λ}_{3} {M}_{3} + {λ}_{4} {M}_{4} \qquad 〈 Equation 3 〉$$

Here, M may represent the Mueller matrix, Mᵢ may represent a non-depolarizing sub-matrix, and λᵢ may represent a weight corresponding to each non-depolarizing sub-matrix. Based on the weight value, a main non-depolarizing component may be determined. For example, the non-depolarizing sub-matrix with the largest weight value may be the main non-depolarizing component.

FIG. 6 illustrates the examples 610, 620, 630, and 640 of the sum-decomposed non-depolarizing sub-matrices. In the illustrated examples 610, 620, 630, and 640, the horizontal axis of each matrix component may represent a wavelength and the vertical axis may represent a value of the matrix component. The controller may calculate a Hermitian matrix of the Mueller matrix and calculate a weight value by using an eigenvalue of the calculated Hermitian matrix. In addition, the controller may calculate a non-depolarizing sub-matrix by using the eigenvalue matrix of the Hermitian matrix.

The controller may use at least some of the plurality of decomposed non-depolarizing sub-matrices (or a result of performing an appropriate operation on at least some of the decomposed non-depolarizing sub-matrices) as depolarization information. The controller may use, as depolarization information, at least some sub-matrices associated with the depolarization element of reflected light among the plurality of decomposed non-depolarizing sub-matrices and/or a weight corresponding to each of the at least some sub-matrices.

The controller may identify at least some sub-matrices associated with the depolarization element of reflected light among the plurality of sub-matrices by using the weight value. For example, the controller may compare relative sizes between weight values and may identify a specific weight value and a sub-matrix corresponding thereto based on the comparison result. The controller may use the identified weight value and/or sub-matrix as depolarization information. Additionally or alternatively, the controller may use, as depolarization information, a weighted sum of sub-matrices (e.g., λ₂M₂+λ₃M₃+λ₄M₄) having weights less than or equal to a threshold.

FIG. 7 is a diagram illustrating an example 700 of an index related to the degree of depolarization. The controller may extract depolarization information by calculating an index related to the degree to which the polarization state is reduced (i.e., the degree of depolarization) based on the Mueller matrix.

The controller may calculate a depolarization index (DI) based on the Mueller matrix. The depolarization index may be an index representing the degree to which the polarization state of reflected light is depolarized compared to incident light. For example, the depolarization index may be calculated by Equation 4 presented below.

$$DI = 1 - \sqrt{\frac{tr ( {M}^{T} M ) - {m}_{00}^{2}}{3 {m}_{00}^{2}}} \qquad 〈 Equation 4 〉$$

Here, M may represent the Mueller matrix, MT may represent a transposed matrix of the Mueller matrix, tr(·) may represent a sum of diagonal components, i.e., trace, and moo may represent the total intensity of incident light. The depolarization index may have a value between 0 and 1, and as the depolarization index is closer to 1, the degree to which the polarization state is reduced (i.e., the degree of depolarization) is greater, and as the depolarization index is closer to 0, the degree to which the polarization state is maintained is greater.

Since the Mueller matrix may be calculated for each wavelength, the depolarization index calculated based on the Mueller matrix may also be calculated for each wavelength. In the illustrated example 700, the horizontal axis of each matrix component may represent a wavelength and the vertical axis may represent a value of the depolarization index.

Additionally or alternatively, the controller may calculate a degree of polarization (DoP) based on the Mueller matrix. The degree of polarization may be an index representing the degree to which the polarization state of reflected light is maintained. For example, the degree of polarization may be calculated by Equation 5 presented below.

$$DoP = \sqrt{\frac{tr ( {M}^{T} M ) - {m}_{00}^{2}}{3 {m}_{00}^{2}}} \qquad 〈 Equation 5 〉$$

For example, the degree of polarization may be a value (DoP=1-DI) obtained by subtracting a depolarization index from 1. The degree of polarization may have a value between 0 and 1, and as the degree of polarization is closer to 0, the degree to which the polarization state is reduced is greater, and as the degree of polarization is closer to 1, the degree to which the polarization state is maintained is greater.

Additionally or alternatively, the controller may calculate an average DoP based on the Mueller matrix. The average DoP may be an average of degrees of polarization of a polarization state varying over the entire Poincaré sphere. For example, the average DoP may be calculated by Equation 6 presented below:

$$Average DoP = \frac{1}{4 π} {\int }_{0}^{π} {\int }_{0}^{2 π} DoP [ M \cdot S ( θ , ϕ ) ] cos ( ϕ ) d θ d ϕ \qquad 〈 Equation 6 〉$$

Here, M may represent the Mueller matrix, S (0, ¢) may represent a Stokes vector representing a specific polarization state on the Poincaré sphere, θ may represent a main axis direction of a polarization ellipse, and @ may represent a degree of circular polarization.

The average DoP may have a value between 0 and 1, and as the average DoP is closer to 0, the degree to which the polarization state is reduced is greater, and as the average DoP is closer to 1, the degree to which the polarization state is maintained is greater.

Additionally or alternatively, the controller may calculate a weighted DoP based on the Mueller matrix. The weighted DoP may be a weighted average of degrees of polarization which use an exiting flux as a weight. For example, the weighted DoP may be calculated by Equation 7 presented below.

$$Weighted DoP = \frac{{\int }_{0}^{π} {\int }_{0}^{π / 2} ( M [ 0 ] \cdot S ( θ , ϕ ) ) DoP [ M \cdot S ( θ , ϕ ) ] cos ( ϕ ) d θ d ϕ}{{\int }_{0}^{π} {\int }_{0}^{π / 2} ( M [ 0 ] \cdot S ( θ , ϕ ) ) cos ( ϕ ) d θ d ϕ} \qquad 〈 Equation 7 〉$$

Here, M may represent the Mueller matrix, M[0] may represent the first row of the Mueller matrix, S(θ, ϕ) may represent the Stokes vector representing a specific polarization state on the Poincaré sphere, θ may represent a main axis direction of a polarization ellipse, ϕ may represent a degree of circular polarization, and M[0]·S(θ, ϕ) may represent the exiting flux.

The weighted DoP may have a value between 0 and 1, and as the weighted DoP is closer to 0, the degree to which the polarization state is reduced is greater, and as the weighted DoP is closer to 1, the degree to which the polarization state is maintained is greater.

At least one of the above-described indexes (e.g., the depolarization index, the degree of polarization, the average degree of polarization, the weighted degree of polarization, etc.) related to the degree to which the polarization state is reduced may be used as depolarization information. Being used as depolarization information may include not only being directly used as the depolarization information, but also being directly or indirectly used for other types of information used as the depolarization information.

FIG. 7 illustrates the example 700 of the calculated depolarization information. In the illustrated example 700, the horizontal axis may represent a wavelength and the vertical axis may represent a depolarization index. As shown in the illustrated example 700, the depolarization information may be extracted as spectrum data for each wavelength.

FIG. 8 is a diagram illustrating an example of calculating depolarization information 500 by using a dispersion prediction model 800. Referring to FIG. 8, the controller may calculate a local dispersion 810 by using the dispersion prediction model 800 which is configured to output data related to the local dispersion 810 based on input data related to the depolarization information 500.

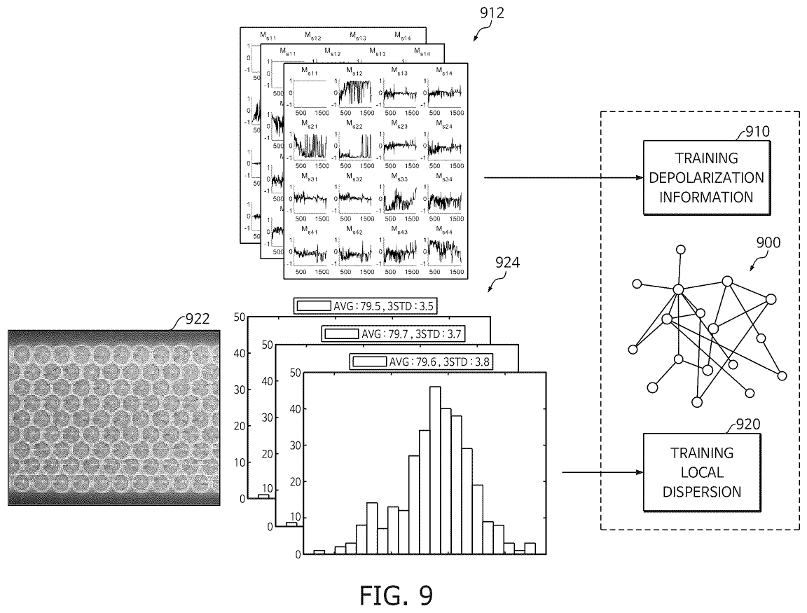

The dispersion prediction model 800 may be a model that is generated through training using a training data set extracted from a training sample. For example, the dispersion prediction model 800 may include a machine learning model that is generated by machine learning based on a training data set extracted from a training sample. In another example, the dispersion prediction model 800 may include a linear model that is generated by linear regression based on a training data set extracted from a training sample. This will be described in more detail below with reference to FIGS. 9 to 11.

FIG. 9 is a diagram illustrating an example of a data set for training a dispersion prediction model 900. Referring to FIG. 9, the dispersion prediction model 900 may be a model that is trained by using a correlation between a first data set including training depolarization information 910 and a second data set including a training local dispersion 920. The first data set may include the training depolarization information 910 which is extracted from polarization spectrum data 912 on each of various measurement areas of the training sample. A process of acquiring the training the polarization spectrum data 912 from each of the various measurement areas of the training sample and extracting the training depolarization information 910 may be performed in the same/similar manner as/to the process described above with reference to FIGS. 1 to 7.

The second data set may include the training local dispersion 920 corresponding to the training depolarization information 910 included in the first data set. The second data set may include the training local dispersion 920 which is calculated based on critical dimension information 924 measured from the training sample or an image 922 resulting from photographing of the training sample. For example, the training local dispersion 920 may be information that is measured through a highly accurate critical dimension measurement technique such as an imaging technique (e.g., an imaging technique using scanning electron microscope (SEM), transmission electron microscope (TEM), atomic force microscope (AFM)).

The first data set and the second data set may include training data on various measurement areas of one training sample, or may include training data on each of the various measurement areas of each of a plurality of training samples.

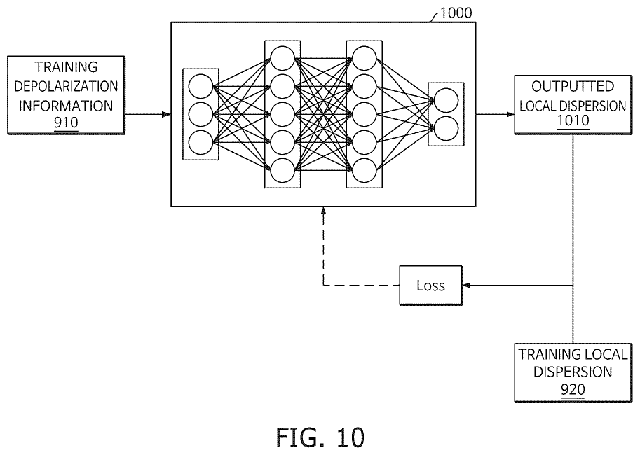

FIG. 10 is a diagram illustrating an example of a method for generating a dispersion prediction model 1000. The dispersion prediction model 1000 may include a machine learning model that is generated by machine learning based on a training data set extracted from a training sample. The machine learning model may refer to any model that is used to infer an answer to a given input. The machine learning model may include an artificial neural network model including an input layer, a plurality of hidden layers, and an output layer, but is not limited thereto.

The dispersion prediction model 1000 may be supervised and trained to infer the training local dispersion 920 from the training depolarization information 910. For example, by inputting the training depolarization information 910 to the dispersion prediction model 1000, a local dispersion 1010 may be outputted. A loss may be calculated based on the outputted local dispersion 1010 and the training local dispersion 920, and training may be performed by adjusting a weight of the dispersion prediction model 1000 to minimize the calculated loss. The training method described above is only an example, and any training method such as unsupervised learning, self-supervised learning, reinforcement learning, and other supervised learning methods may be used for training the dispersion prediction model 1000.

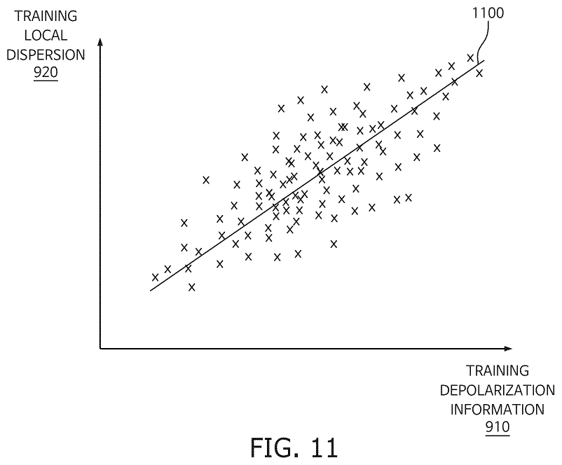

FIG. 11 is a diagram illustrating an example of a method for generating a dispersion prediction model 1100. The dispersion prediction model 1100 may include a linear model that is generated by linear regression based on a training data set extracted from a training sample. For example, first, a linear model which has depolarization information as an independent variable and a local dispersion as a dependent variable may be defined. A linear model in which a loss between the linear model and data pairs including the training depolarization information 910 and the training local dispersion 920 corresponding to the training depolarization information 910 is minimized may be determined as the dispersion prediction model 1100. The loss may be calculated by various methods such as the method of least squares, etc.

Although FIG. 11 illustrates that depolarization information (training depolarization information and/or depolarization information which is an independent variable of the dispersion prediction model 1100) is one-dimensional information, this is merely for the convenience of explanation and embodiments are not limited thereto. The depolarization information may be one-dimensional information or multi-dimensional information. If the depolarization information is multi-dimensional information, the dispersion prediction model 1100 may include a multiple linear model that is generated using multiple linear regression. The above-described linear model is only an example, and a nonlinear model or other various statistical analysis models may be used as the dispersion prediction model 1100.

FIG. 12 is a diagram illustrating an example of calculating the local dispersion 810. The controller may calculate the local dispersion 810 by using a spectrum prediction model 1200. The spectrum prediction model 1200 may represent an expected polarization spectrum 1230 according to a local average condition 1210 of a critical dimension and a local dispersion condition 1220 of the critical dimension. In a specific example, the spectrum prediction model 1200 may be expressed as shown in Equation 8.

$${M}_{m} ( \overline{CD} , σ ) = {\int }_{\overline{CD} - 3 σ}^{\overline{CD} + 3 σ} ρ ( CD ) {M}_{theory} ( C D ) d C D \qquad 〈 Equation 8 〉$$

Here, Mₘ may represent the expected polarization spectrum 1230, CD may represent the critical dimension, M_{theory} (CD) may represent a theoretical spectrum according to a critical dimension value, p(CD) may represent a critical dimension-related Gaussian weight

$$( i . e . , N ( \overline{CD} , σ ) = \frac{1}{σ2 π} {e}^{- \frac{1}{2} {( \frac{CD - \overline{CD}}{σ} )}^{2}} ) ,$$

C̅D̅ may represent the local average condition 1210 of the critical dimension, and σ may represent the local dispersion condition 1220 of the critical dimension.

The controller may estimate a local dispersion of the critical dimension by comparing expected depolarization information 1240, which is extracted by using the spectrum prediction model 1200, and the depolarization information 500, which is extracted based on an electrical signal outputted by an ellipsometer. For example, first, the controller may calculate a local average of the critical dimension of a target sample based on an electrical signal outputted by the ellipsometer, by measuring on a measurement area of the target sample. In addition, the controller may extract the depolarization information 500 based on the electrical signal outputted by the ellipsometer. The controller may estimate the local dispersion 810 of the critical dimension by comparing the expected depolarization information 1240 under various local dispersion conditions 1220 with the depolarization information 500 extracted for the target sample in a state where the local average condition 1210 is fixed to the calculated local average. For example, the controller may determine, as the local dispersion 810 within the measurement area of the target sample, the local dispersion condition 1220 corresponding to the expected depolarization information 1240 which is most similar to the depolarization information 500 extracted for the target sample among the expected depolarization information 1240 under various local dispersion conditions 1220 obtained by using the spectrum prediction model 1200. The similarity may be determined by any similarity calculation method, such as a method based on the method of least squares, etc.

FIG. 13 is a diagram illustrating an example of calculating the local dispersion 810. The controller may calculate the local dispersion 810 by using a spectrum prediction model 1300. The spectrum prediction model 1300 may represent an expected polarization spectrum 1330 according to a wavelength band condition 1310, an incident angle range condition 1320 of incident light, the local average condition 1210 of a critical dimension and the local dispersion condition 1220 of the critical dimension. In a specific example, the spectrum prediction model 1300 may be expressed as shown in Equation 9.

$${M}_{m} ( \overline{CD} , σ ) = {\int }_{B W} {\int }_{AOI} {\int }_{\overline{CD} - 3 σ}^{\overline{CD} + 3 σ} {w}_{λ} ( λ ) {w}_{θ} ( θ ) ρ ( CD ) {M}_{theory} ( CD , θ , λ ) dCD d θ d λ \qquad 〈 Equation 9 〉$$

Here, Mₘ may represent the expected polarization spectrum 1330, CD may represent the critical dimension, θ may represent an incident angle of incident light, λ may represent a wavelength of incident light, M_{theory} (CD, θ, λ) may represent a theoretical spectrum according to a critical dimension, an incident angle, and a wavelength, p(CD) may represent a critical dimension-related Gaussian weight, w_{θ}(θ) may represent an incident angle-related weight, w_{λ}(λ) may represent a wavelength-related weight, C̅D̅ may represent the local average condition 1210 of the critical dimension, σ may represent the local dispersion condition 1220 of the critical dimension, AOI may represent the incident angle range condition 1320 of incident light, and BW may represent the wavelength band condition 1310. The incident angle-related weight (w_{θ}(θ)) and the wavelength-related weight (w_{λ}(λ)) may be experimentally determined according to an ellipsometer facility.

For example, according to the above-described spectrum prediction model 1300, it may be seen that not only the critical dimension of the target sample, but also the facility-related elements of the ellipsometer (a wavelength band, an incident angle range, etc.) may affect the measured spectrum.

The controller may calculate the local dispersion 810 of the critical dimensions of the target sample based on the depolarization information 500, by using the spectrum prediction model 1300 representing the expected polarization spectrum 1330 according to the wavelength band condition 1310, the incident angle range condition 1320 of incident light, the local average condition 1210 of the critical dimension, and the local dispersion condition 1220 of the critical dimension. In this case, the influence of facility-induced elements (a wavelength band, an incident angle range, etc.) may be removed from the calculated local dispersion 810, so that the local dispersion 810 of the critical dimension may be more accurately calculated. For example, the controller may remove the facility-induced elements from the depolarization information 500, and may separately calculate the local dispersion 810 of the critical dimension which is a target sample-induced element.

For example, first, the controller may calculate a local average of the critical dimension of the target sample based on an electrical signal outputted by the ellipsometer. In addition, the controller may extract the depolarization information 500 based on the electrical signal outputted by the ellipsometer. The controller may fix the wavelength band condition 1310 and the incident angle range condition 1320 of the incident light to a wavelength band and an incident angle range according to a facility or measurement condition of the ellipsometer, and may estimate the local dispersion 810 of the critical dimension by comparing expected depolarization information 1340 under various local dispersion conditions 1220 with the depolarization information 500 extracted for the target sample in a state where the local average condition 1210 is fixed to the calculated local average.

FIG. 14 is a diagram illustrating an example of an experimental result showing a correlation between depolarization information and a local dispersion of a critical dimension. Referring to FIG. 14, in the first to sixth examples 1410, 1420, 1430, 1440, 1450, and 1460, the horizontal axis represents a wavelength and the vertical axis represents depolarization information (for example, a depolarization index).

Graphs according to various examples are illustrated in each example 1410, 1420, 1430, 1440, 1450, and 1460. The graphs according to various examples may show experimental results on samples having different local dispersions of critical dimensions, respectively. In each of the examples 1410, 1420, 1430, 1440, 1450, and 1460, the graph according to Example 1 may show an experimental result on a sample having the highest local dispersion of the critical dimension, and the graph according to Example 3 may show an experimental result on a sample having the lowest local dispersion of the critical dimension. Referring to FIG. 14, it may be seen in each example 1410, 1420, 1430, 1440, 1450, and 1460 that, as the local dispersion of the critical dimension is higher (i.e., from Example 3 to Example 1), the value of the depolarization information (specifically, the depolarization index) is higher. That is, it can be identified that there is a correlation between the local dispersion of the critical dimension and the depolarization information.

In addition, each of the examples 1410, 1420, 1430, 1440, 1450, and 1460 may show an example of an experimental result under a different incident angle range condition of incident light. Examples of experimental results under the conditions of wider incident angle ranges (larger spread) from the first example 1410 to the sixth example 1460 are shown. Referring to FIG. 14, it may be seen that the value of the depolarization information is higher from the first example 1410 to the sixth example 1460, that is, as the range of the incident angle is wider. For example, it can be identified that there is also a correlation between the range of the incident angle (facility-induced element) and the depolarization information.

FIG. 15 is a diagram illustrating an example of a degree of consistency between a local dispersion calculated according to various methods and a reference local dispersion. Referring to FIG. 15, in an illustrated example 1500, the horizontal axis represents the layer of a target sample (specifically, the position of a word line in a 3D memory device), and the vertical axis represents a degree of consistency R² between a local dispersion calculated in each layer of the target sample and a reference local dispersion. The reference local dispersion may be local dispersion information that is measured by a highly accurate method such as an imaging technique (e.g., Scanning Probe Acoustic Microscopy, SPAS), etc.

Related examples 1 and 2 may show examples of calculating a local dispersion by using the entire polarization spectrum data without extracting depolarization information from polarization spectrum data. An example may represent an example of extracting depolarization information from polarization spectrum data and calculating a local dispersion by using the depolarization information. Referring to the illustrated example 1500, it can be seen that the degree of consistency with the reference local dispersion is higher in the example in which the local dispersion is calculated by using depolarization information, compared to the related examples in which a local dispersion is calculated by using the entire polarization spectrum data. For example, when depolarization information is extracted based on polarization spectrum data and a local dispersion is calculated by using the extracted depolarization information, more accurate local dispersion information may be acquired than when the entire polarization spectrum data is used.

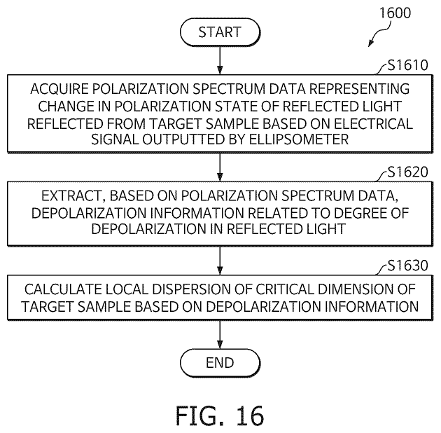

FIG. 16 is a flowchart illustrating an example of a method 1600 of calculating a local dispersion of a critical dimension. The method 1600 may be performed by at least one processor (e.g., at least one processor of the controller).

First, the processor may acquire polarization spectrum data based on an electrical signal outputted by the ellipsometer, at operation S1610. The polarization spectrum data may include data representing a change in the polarization state in reflected light reflected from a target sample compared to incident light emitted to the target sample. For example, the processor may calculate a Mueller matrix representing a change in the polarization state for each wavelength of reflected light based on the electrical signal outputted by the ellipsometer.

The processor may extract depolarization information based on the polarization spectrum data, at operation S1620. The depolarization information may include information related to the degree to which the polarization state in the reflected light is reduced compared to the incident light.

The processor may extract the depolarization information by calculating an index related to the degree to which the polarization state is reduced based on the Mueller matrix. For example, the processor may calculate at least one of a depolarization index, a degree of polarization, an average degree of polarization, and a weighted degree of polarization based on the Mueller matrix.

Additionally or alternatively, the processor may decompose the Mueller matrix into a plurality of sub-matrices to extract the depolarization information. For example, the processor may decompose the Mueller matrix into a product of a polarization transformation matrix associated with a depolarization element of reflected light, a polarization rotation matrix associated with a phase retardation element of reflected light, and a polarization diattenuation matrix associated with a diattenuation element of reflected light, and may extract the polarization transformation matrix (or a result of performing an appropriate operation on the polarization transformation matrix) as depolarization information. In another example, the processor may decompose the Mueller matrix into a weighted sum of a plurality of non-depolarizing sub-matrices, and may extract at least some sub-matrices associated with a depolarization element of reflected light among the plurality of decomposed non-depolarizing sub-matrices and/or a weight corresponding to each of the at least some sub-matrices (or result of performing an appropriate operation) as depolarization information.

The processor may calculate a local dispersion of the critical dimension of the target sample based on the extracted depolarization information, at operation S1630. The processor may calculate the local dispersion of the critical dimension of the target sample from the depolarization information by using a dispersion prediction model, which is modeled by using a correlation between a first data set related to the depolarization information and a second data set related to the local dispersion of the critical dimension. The first data set may include depolarization information extracted from polarization spectrum data on a training sample, and the second data set may include a local dispersion calculated based on critical dimension information measured from the training sample or an image acquired from the training sample.

For example, the processor may calculate the local dispersion of the critical dimension of the target sample from the depolarization information by using the dispersion prediction model, which includes a linear model generated by linear regression based on the first data set and the second data set. In another example, the processor may calculate the local dispersion of the critical dimension of the target sample from the depolarization information by using the dispersion prediction model, which includes a machine learning model generated by machine learning based on the first data set and the second data set.

Additionally or alternatively, the processor may calculate the local dispersion by using a model representing expected polarization spectrum data according to a local average condition of the critical dimension and a local dispersion condition of the critical dimension. Additionally or alternatively, the processor may calculate the local dispersion by using a model representing expected polarization spectrum data according to a wavelength band condition, an incident angle range condition of incident light incident on the target sample, a local average condition of the critical dimension, and a local dispersion condition of the critical dimension. For example, the processor may estimate the local dispersion of the critical dimension by comparing expected depolarization information which is extracted by using a model, and depolarization information which is extracted through measurement on the target sample.

The flowchart illustrated in FIG. 16 and the above description are merely examples, and embodiments are not limited thereto. For example, according to another example, at least one step may be added/changed/removed, the order of each step may be changed, or at least one step may be performed by a component other than the processor.

Embodiments of the present disclosure have been described above for purposes of illustration only, and those skilled in the art with ordinary knowledge of the present disclosure will be able to make various modifications, changes and additions within the spirit and scope of the present disclosure, and such modifications, changes and additions should be construed to be included in a scope of the claims and their equivalents.

It should be understood that those of ordinary skill in the art to which the present disclosure pertains can make various substitutions, modifications and changes without departing from the technical spirit of the present disclosure, and thus, the present disclosure is not limited by the examples described above and the accompanying drawings.

What is claimed is:

1. A method for measuring a semiconductor device by an electronic device, wherein the electronic device comprises a light source assembly comprising a light source configured to emit light and a first optical system in a traveling path of the light emitted from the light source, a light reception assembly comprising a second optical system in a traveling path of reflected light which is reflected from a target sample after passing through the first optical system, and a detector configured to detect the reflected light that passed through the second optical system, and at least one processor configured to process an electrical signal outputted from the light reception assembly and obtain a dispersion of a critical dimension of the target sample, the method comprising:
obtaining polarization spectrum data corresponding to a change in a polarization state of the reflected light based on the electrical signal outputted by the light reception assembly;
extracting, based on the polarization spectrum data, depolarization information corresponding to a degree of depolarization in the reflected light; and
obtaining the dispersion of the critical dimension of the target sample based on the depolarization information.

2. The method of claim 1, wherein the acquiring the polarization spectrum data comprises:
obtaining a Mueller matrix corresponding to a change in the polarization state of each wavelength of the reflected light based on the electrical signal outputted by the light reception assembly; and
extracting the depolarization information based on the Mueller matrix.

3. The method of claim 2, wherein the extracting the depolarization information based on the Mueller matrix comprises obtaining a degree of polarization (DoP) based on the Mueller matrix, and
wherein the obtaining the dispersion of the critical dimension of the target sample based on the depolarization information comprises obtaining the dispersion of the critical dimension of the target sample based on the degree of polarization.

4. The method of claim 2, wherein the extracting the depolarization information based on the Mueller matrix comprises obtaining an average DoP based on the Mueller matrix, and
wherein the obtaining the dispersion of the critical dimension of the target sample based on the depolarization information comprises obtaining the dispersion of the critical dimension of the target sample based on the average DoP.

5. The method of claim 2, wherein the extracting the depolarization information based on the Mueller matrix comprises obtaining a weighted DoP based on the Mueller matrix, and
wherein the obtaining the dispersion of the critical dimension of the target sample based on the depolarization information comprises obtaining the dispersion of the critical dimension of the target sample based on the weighted DoP.

6. The method of claim 2, wherein the extracting the depolarization information based on the Mueller matrix comprises obtaining a depolarization index (DI) based on the Mueller matrix, and
wherein the obtaining the dispersion of the critical dimension of the target sample based on the depolarization information comprises obtaining the dispersion of the critical dimension of the target sample based on the depolarization index.

7. The method of claim 2, wherein the extracting the depolarization information based on the Mueller matrix comprises decomposing the Mueller matrix into a product of a plurality of sub-matrices corresponding to the change in the polarization state of the reflected light, and
wherein the obtaining the dispersion of the critical dimension of the target sample based on the depolarization information comprises obtaining the dispersion of the critical dimension of the target sample based on at least some of the plurality of decomposed sub-matrices.

8. The method of claim 7, wherein the extracting the depolarization information based on the Mueller matrix comprises decomposing the Mueller matrix into a product of a polarization transformation matrix corresponding to a depolarization element of the reflected light, a polarization rotation matrix corresponding to a phase retardation element of the reflected light, and a polarization diattenuation matrix corresponding to a diattenuation element of the reflected light, and
wherein the obtaining the dispersion of the critical dimension of the target sample based on the depolarization information comprises obtaining the dispersion of the critical dimension of the target sample based on the polarization transformation matrix.

9. The method of claim 2, wherein the extracting the depolarization information based on the Mueller matrix comprises decomposing the Mueller matrix into a weighted sum of a plurality of non-depolarizing sub-matrices, and
wherein the obtaining the dispersion of the critical dimension of the target sample based on the depolarization information comprises obtaining the dispersion of the critical dimension of the target sample based on at least some sub-matrices corresponding to the depolarization element of the reflected light among the plurality of decomposed non-depolarizing sub-matrices, and a weight corresponding to each of the at least some sub-matrices.

10. The method of claim 1, wherein the obtaining the dispersion of the critical dimension of the target sample based on the depolarization information comprises obtaining the dispersion of the critical dimension of the target sample from the depolarization information based on a dispersion prediction model, the dispersion prediction model being modeled based on a correlation between a first data set related to the depolarization information and a second data set corresponding to the dispersion of the critical dimension,
wherein the first data set comprises depolarization information extracted from polarization spectrum data on a training sample, and
wherein the second data set comprises a dispersion which is obtained based on critical dimension information from the training sample or an image from photographing of the training sample.

11. The method of claim 10, wherein the dispersion prediction model comprises a linear model that is generated by linear regression based on the first data set and the second data set.

12. The method of claim 10, wherein the dispersion prediction model comprises a machine learning model that is generated by machine learning based on the first data set and the second data set.

13. The method of claim 1, wherein the obtaining the dispersion of the critical dimension of the target sample based on the depolarization information comprises estimating the dispersion of the critical dimension by comparing expected depolarization information, which is extracted based on a model corresponding to expected polarization spectrum data based on an average condition of the critical dimension and a dispersion condition of the critical dimension, with the depolarization information.

14. The method of claim 1, wherein the obtaining the dispersion of the critical dimension of the target sample based on the depolarization information comprises estimating the dispersion of the critical dimension by comparing expected depolarization information, which is extracted based on a model corresponding to expected polarization spectrum data according to a wavelength band condition, an incident angle range condition of incident light entering the target sample, an average condition of the critical dimension, and a dispersion condition of the critical dimension, with the depolarization information.

15. The method of claim 1, wherein the target sample comprises a semiconductor element, and
wherein the critical dimension of the target sample comprises a critical dimension of a fine pattern included in the semiconductor element.

16. The method of claim 1, wherein the first optical system comprises a polarizer configured to polarize the light emitted from the light source, and
wherein the second optical system comprises an analyzer configured to analyze the polarization state of the reflected light.

17. The method of claim 16, wherein the first optical system further comprises a first compensator configured to modulate a phase of the light passed through the polarizer, and
wherein the second optical system further comprises a second compensator configured to modulate a phase of the reflected light.

18. A method for measuring a semiconductor device using an electronic device, wherein the electronic device comprises an ellipsometer configured to output an electrical signal for a critical dimension of the target sample by emitting incident light having a specific polarization state to a target sample, and detecting reflected light reflected from the target sample, and at least one processor configured to process the electrical signal outputted by the ellipsometer and obtain a dispersion of the critical dimension of the target sample, the method comprising:
obtaining, polarization spectrum data corresponding to a change in the polarization state of the reflected light based on the electrical signal outputted by the ellipsometer;
extracting, based on the polarization spectrum data, depolarization information corresponding to a degree of depolarization in the reflected light; and
obtaining the dispersion of the critical dimension of the target sample based on the depolarization information.

19. A method for measuring a semiconductor device, the method being performed by at least one processor and comprising:
obtaining polarization spectrum data corresponding to a change in a polarization state of reflected light reflected from a target sample based on an electrical signal outputted by an ellipsometer;
extracting, based on the polarization spectrum data, depolarization information corresponding to a degree of depolarization in the reflected light; and
obtaining the dispersion of the critical dimension of the target sample based on the depolarization information.

20. The method of claim 19, wherein the obtaining the polarization spectrum data comprises obtaining a Mueller matrix corresponding to the change in the polarization state of each wavelength of the reflected light based on the electrical signal, and
wherein the extracting the depolarization information comprises extracting the depolarization information based on at least one of a degree of polarization, an average degree of polarization, a weighted degree of polarization, and a depolarization index, which are obtained from the Mueller matrix.
